(19) United States
(12) Patent Application Publication
(10) Pub. No.: US 2024/0352616 A1
(43) Pub. Date: Oct. 24, 2024

(54) SYSTEMS AND METHODS FOR MICROVOID ANALYSIS IN CRYSTALS GROWN BY CONTINUOUS CZOCHRALSKI PULLERS

(71) Applicant: GlobalWafers Co., Ltd., Hsinchu (TW)

(72) Inventors: Matteo Pannocchia, Lana (IT); Francesca Marchese, Merano (IT); Enrico Rigon, Merano (IT)

(21) Appl. No.: 18/635,262

(22) Filed: Apr. 15, 2024

Related U.S. Application Data
(60) Provisional application No. 63/496,830, filed on Apr. 18, 2023.

(51) Int. Cl. C30B 15/26; C30B 15/00; C30B 15/10; C30B 29/06

(52) U.S. Cl. CPC C30B 15/26; C30B 15/002; C30B 15/10; C30B 29/06

(57) ABSTRACT

A computer device includes at least one processor in communication with at least one memory device. The at least one processor is programmed to: a) receive at least one image of a silicon melt of a crystal in a crucible; b) execute a model trained to segment the at least one image into different classes; c) analyze segmentation to determine a quality of the crystal; and/or d) approve or reject the crystal based upon the analysis.

### CROSS-REFERENCE TO RELATED APPLICATIONS

This patent application claims priority to U.S. Provisional Patent Application Ser. No. 63/496,830, filed Apr. 18, 2023, the entire contents and disclosure of which are hereby incorporated herein by reference in its entirety.

### FIELD

The field relates generally to micro-void analysis in crystals grown by Continuous Czochralski pullers, and more specifically to using artificial intelligence analysis of images of silicon melt in triple crucibles to detect and/or predict micro-voids.

### BACKGROUND

The demand for 300 mm diameter silicon wafers heavily doped with arsenic and phosphorus is increasing continuously. This demand can be satisfied very effectively using crystals grown by Continuous Czochralski method (CCz). However, the demand for 300 mm diameter silicon wafers also comes with the requirement for a low void count. Over time the requirement has become stricter, dropping from less than 50 defects per wafer to less than 10 defects per wafer. This requirement requires the technique to control the void count (localized light scatters—LLS) must be refined repeatedly. Accordingly, a system for improving the control of voids capability on 300 mm diameter crystals grown by the CCz method is desired.

This Background section is intended to introduce the reader to various aspects of art that may be related to various aspects of the present disclosure, which are described and/or claimed below. This discussion is believed to be helpful in providing the reader with background information to facilitate a better understanding of the various aspects of the present disclosure. Accordingly, it should be understood that these statements are to be read in this light, and not as admissions of prior art.

### BRIEF DESCRIPTION

In one aspect, a computer system includes a computing device that may include at least one processor in communication with at least one memory device. The at least one processor may be configured to: a) receive at least one image of a silicon melt of a crystal in a crucible; b) execute a model trained to segment the at least one image into different classes; c) analyze segmentation to determine a quality of the crystal; and/or d) approve or reject the crystal based upon the analysis.

In another aspect, a computer-implemented method may be performed by a Continuous Czochralski Image Analysis (CCZIA) computer device including at least one processor in communication with at least one memory device. The method may include: a) receiving at least one image of a silicon melt of a crystal in a crucible; b) executing a model trained to segment the at least one image into different classes; c) analyzing segmentation to determine a quality of the crystal; and/or d) approving or rejecting the crystal based upon the analysis.

In another aspect, at least one non-transitory computer-readable media having computer-executable instructions embodied thereon, when executed by a computing device including at least one processor in communication with at least one memory device, the computer-executable instructions may cause the at least one processor to: a) receive at least one image of a silicon melt of a crystal in a crucible; b) execute a model trained to segment the at least one image into different classes; c) analyze segmentation to determine a quality of the crystal; and/or d) approve or reject the crystal based upon the analysis.

Advantages will become more apparent to those skilled in the art from the following description of the preferred embodiments which have been shown and described by way of illustration. As will be realized, the present embodiments may be capable of other and different embodiments, and their details are capable of modification in various respects. Accordingly, the drawings and description are to be regarded as illustrative in nature and not as restrictive.

### BRIEF DESCRIPTION OF THE DRAWINGS

The Figures described below depict various aspects of the systems and methods disclosed. Each Figure depicts an embodiment of a particular aspect of the disclosed systems and methods, and that each of the Figures is intended to accord with a possible embodiment. Further, wherever possible, the following description refers to the reference numerals included in the following Figures, in which features depicted in multiple Figures are designated with consistent reference numerals.

FIGS. 1A and 1B illustrate schematic representations of three crucibles without and with homogeneous cullet distribution.

FIGS. 2A and 2B illustrate two views of silicon melt rings in crucibles.

FIG. 3A illustrates an example view of a crucible in use.

FIG. 3B illustrates an example labeling scheme of the crucible in use shown in FIG. 3A.

FIGS. 4A and 4B illustrate example views of a crucible in use before and after the image has been segmented using the labeling scheme shown in FIG. 3B.

FIGS. 5A-5D illustrate example stages of crystal growth.

FIGS. 6A-6D illustrate further example stages of crystal growth.

FIG. 7 illustrates an example process of analyzing a Continuous Czochralski method.

FIG. 8 illustrates an example system for performing the process shown in FIG. 7.

FIG. 9 illustrates an example configuration of a user computer device.

FIG. 10 illustrates an example configuration of a server computer device.

Like reference symbols in the various drawings indicate like elements.

### DETAILED DESCRIPTION

The field relates generally to micro-void analysis in crystals grown by Continuous Czochralski (CCz) pullers, and more specifically to using artificial intelligence analysis of images of silicon melt in triple crucibles to detect and/or predict micro-voids. With the CCz process, it is possible to achieve quasi-steady state heat and mass transfer conditions by adding polysilicon and dopant continuously in the annulus between the external and middle crucible, during the growth of the crystal. In a continuous feeding regime, at steady-state conditions, in a certain interval of time the mass of silicon crystal grown equals the amount of polysilicon added to the melt to have a mass balance and maintain constant the silicon melt volume.

The generation of voids in the crystal and therefore in the wafers is intrinsically related to CCz methodology. In fact, the continuous addition of poly silicon feedstock during the crystal growth potentially creates argon bubbles in the melt. The bubbles have with dimensions typically equal or lower than 10 um and can be carried by the silicon melt flowing between adjacent melt zones. The bubbles can be incorporated into the crystal thereby forming voids. This phenomenon is well known for CCz methodologies and historically the voids issues found on the wafers caused major limitations in CCz process utilization.

On 200 mm crystals pulled by CCz, a methodology to control the melt properties and avoid the inclusion of voids into the crystal by using small quartz pieces called “cullets” has been used. The cullets function as barriers generating a tortuous path for the melt to follow.

The process of using cullets in the silicon melt is used to prevent the formation of micro-voids. The aim is to create a tortuous path to the silicon melt to move from outer zone into inner zone to reduce micro voids in 200 mm crystals grown by the CCz method. The quartz bodies have cylindrical shape but may be any size and shape. The cullets can be placed in the outer crucible zone between the outer and middle crucible. In other configurations, the cullets are positioned within the transition zone, between the inner and the middle crucible. During the CCz process, the quartz bodies are be consumed by the melt. It is then necessary to replenish with fresh quartz bodies.

This use of cullets controls micro-void formation on crystals grown using CCz method by including quartz bodies in the poly silicon charge in the first crystal and by replenishing quartz bodies at the end of crystal growth to guarantee low micro voids in the further crystal due the quartz bodies consumption. However, this solution was found ineffective in the case of 300 mm diameter crystals.

One solution to the problem of 300 mm diameter crystals is based on controlling the ratio between the cullets weight in grams added before the start of crystal growth and the interval of time elapsed in hours between cullets addition by feeder system and the start of crystal body growth. With the proper ratio, the voids inclusion at crystal/silicon melt interface are lower than specification limit of 30 for a 300 mm diameter crystal. Specifically, the proper ratio is 60 g/hr, where in melts where the ratio is greater than 60 g/hr the void inclusion at the crystal/silicon surface is lower.

The efficiency of using cullets depends on the distribution of submerged cullets and floating cullets in the external silicon melt annulus. The submerged cullets derive mainly from the cullets amount placed on the initial polysilicon solid charge, the floating cullets mainly from the amount that is dumped by feeder on top of the melt. A uniform distribution may lead to an increased efficiency by reducing the amount of micro bubble formation by their cushioning effect and by increasing their filtering effect by forming an extensive path in the melt.

The present disclosure describes using a camera and artificial intelligence to determine if the cullets distribution in the external annulus is uniform or non-uniform.

The present disclosure is configured for cases just below the proper ratio of 60 g/hr, in which the voids count was not always lower than 30 (@0.2 um) and to manage the updated specification limit of 10 (@0.2 um).

Knowing the distribution of the cullets in the external annulus is fundamental to proper crystal growth in order to be sure that the wafers product from the growth crystal, will be in spec for micro-void counts or not. This solution can be also applied in addition to controlling the ratio between the cullets weight in grams added before the start of crystal growth and the interval of time (in hours) elapsed between cullet addition by feeder system and the start of crystal body grown.

In addition, the solution described includes a check backup if the timer for the cullets discharge does not work or if it does not discharge properly or if there are any anomalies (e.g., growing parameter out of control, for examples crystal diameter). The camera installs for checking the cullets distribution is allows for ensuring that all works well and to know if the wafers void count will be lower than 10 @0.2 um.

This system describes a preventive control system for cullet distribution homogeneity in the external silicon melt annulus. As described herein, a uniform distribution leads to an increased efficiency by reducing the amount of micro bubble formation by their cushioning effect and by increasing their filtering effect by tortuous path in the melt. Without the process described herein, the micro-voids defects are detected downstream of the crystal growth process without any possibility to have feedback before the laser inspection done on silicon wafers.

The cullets are placed in the external annulus of CCz crucibles configuration, in which the polysilicon will be discharge continuously to maintain a constant melt level. The cullets cover the entire polysilicon annulus surface, in order to avoid empty space in which the discharged polysilicon will go directly in contact with the melt (causing the formation of microbubbles in silicon melt).

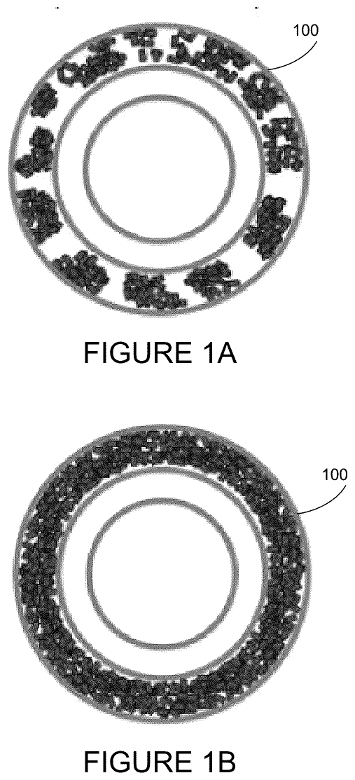

FIGS. 1A and 1B illustrate schematic representations of three crucibles without and with homogeneous cullet distribution. FIGS. 1A and 1B illustrate schematic representation of the three crucibles 100 from above. More specifically, FIG. 1A shows (in a schematic way) a non-optimal condition before crystal growth because of the non-homogeneous cullets distribution. FIG. 1B instead represents an optimal condition before crystal growth because of the homogeneous cullets distribution.

To ensure a good void count capability in silicon monocrystals growth with CCz technology, it is particularly important to guarantee that the cullets are homogeneously distributed in the crucible's external annulus. The cullets should cover the entire polysilicon annulus surface before the crystal body start and during crystal growing. This can be achieved with the installation of a camera combined with artificial intelligence. The code help to identify good situations (like the one schematically represented in FIG. 1B) from potentially dangerous situations (like the one schematically represented in FIG. 1A).

Every crystal with a ratio higher than the proper ratio of 60 g/hr has a good void count capability. Since this ratio is so fundamental to have 300 mm crystal diameter without micro-voids incorporation, during the crystal run there is a timer installed on the puller to have the correct ratio. Before shipping the crystal, the ratio will be checked and if for some reason the ratio is not good the crystal will be not shipped. The ratio (even if it is the most important parameter to have void count control) is not the only parameter to judge the safety of the crystal in terms of micro-voids incorporation. In fact, in some crystal segments, the void count can be higher than 10 counts (current more stringent limit) even if the proper ratio was achieved. There are some situations that could occur during the crystal body phase in which the homogenous cullet layer could be stressed modifying its structure. For example, when sudden feeder issues in which the quantity of poly silicon feeding is not constant, and it could perturb the cullet layer making the cullet layer less homogenous. In other cases, a child crystal with a proper ratio could have a cullet distribution different than standard process of record (POR) situation since its parent crystal did not have the right cullet addition, and so the child crystal has not the same standard amount of cullets. In these cases, considering just the ratio could not be sufficient to guarantee the void count capability because could not be always representative of the real cullet distribution. In another situation, the crystal may have the ratio quite closer to the critical limit of the proper ratio. In these cases, the ratio may be lower than critical limit and potentially lead to the presence of micro-voids generation. Since the ratio is lower than critical threshold, there is the potential of the presence of micro-voids, such that the cullet distribution layer should be analyzed by a camera to determine the risk to have micro-voids. This will improve yield and reduce the number of crystals that will be not shipped.

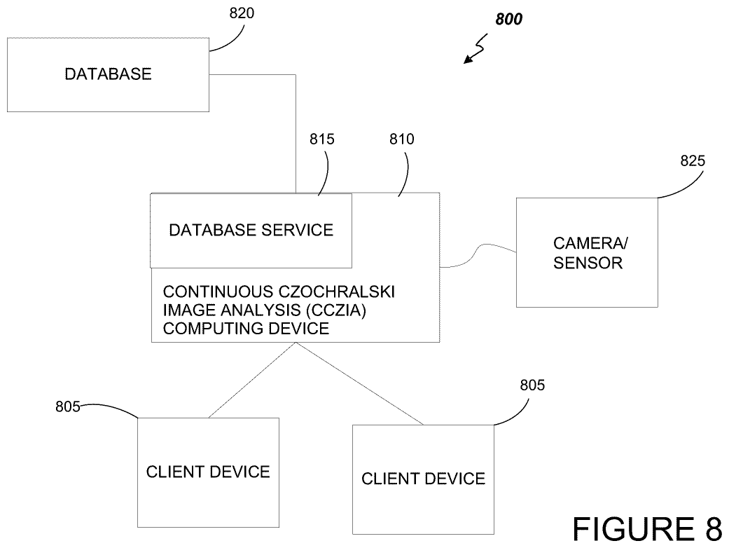

Any additional control that could be done during the crystal process to make sure the crystal is voids free before the laser inspection on wafers is particularly important, especially in the cases explained above. Applying a monitoring camera perpendicular to the external silicon melt annulus in a circular portion of 4 cm diameter to evaluate the cullet distribution during the crystal body phase using one or more models provided by artificial intelligence. The picture of the external silicon melt is captured by the camera 825 (shown in FIG. 8).

In the example embodiments, the process of picture elaboration by the trained models requires considerable computational resources in terms of hardware. In these embodiments, it might not be possible to acquire the pictures every second to improve the processing of the system 800 (shown in FIG. 8). To simplify the process, the image may be acquired at each crucible 100 completed rotation adding a small delay between the previous and the next picture. In this way, it is possible to scan completely the entire external silicon melt ring after some crucible 100 rotations.

The pictures captured and saved are scanned by the Continuous Czochraliski Image Analysis (CCZIA) server 810 (shown in FIG. 8). The CCZIA server 810 executes the one or more models. The one or more models are trained to be able to predict qualitatively the goodness of the cullet layers.

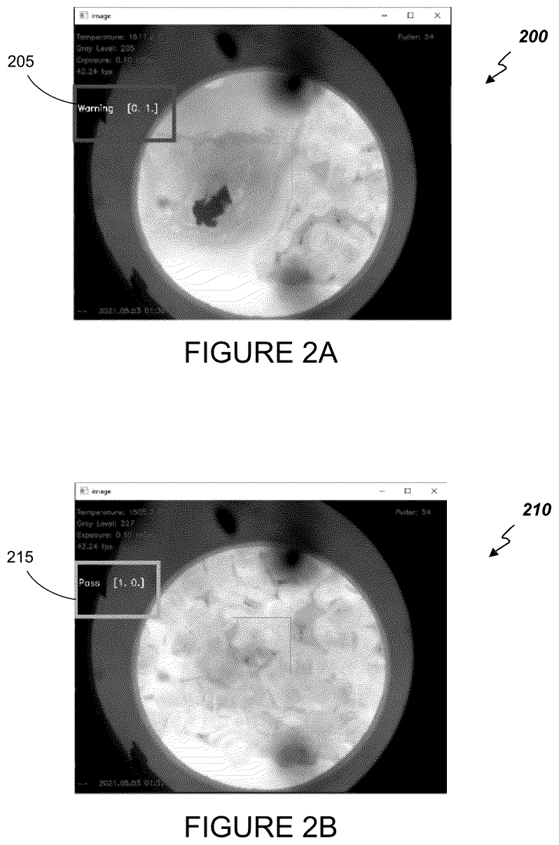

FIGS. 2A and 2B illustrate two views of silicon melt rings in crucibles 100 (shown in FIG. 1). FIGS. 2A and 2B illustrate two pictures where the one or models executed and used the pictures as inputs. In FIG. 2A is related to a picture 200 that was recognized as not optimal conditions and showing a “warning” message 205. FIG. 2B is related to a picture 210 that that was recognized as having good cullet distribution without a liquid zone and showing a “pass” message 215. The goal is to prevent the picture 200 in FIG. 2A because the portion of solid crystal growth could have incorporated micro-bubble of argon due the polysilicon discharge in the liquid zone.

FIGS. 2A and 2B represent two extreme opposite cases. FIG. 2A shows a cullet island with closer a clear silicon liquid melt. FIG. 2B shows a very compact cullet structure. In many cases, the real situation of cullet distribution could be much complicated than the two cases mentioned above. For example, there could be a lot of small islands of cullet with around liquid silicon zone, or there could be a compact cullet layer with small liquid zone above. A quantitative approach is necessary to calculate the percentage of liquid zone in the picture captured by the camera and processed by the AI models.

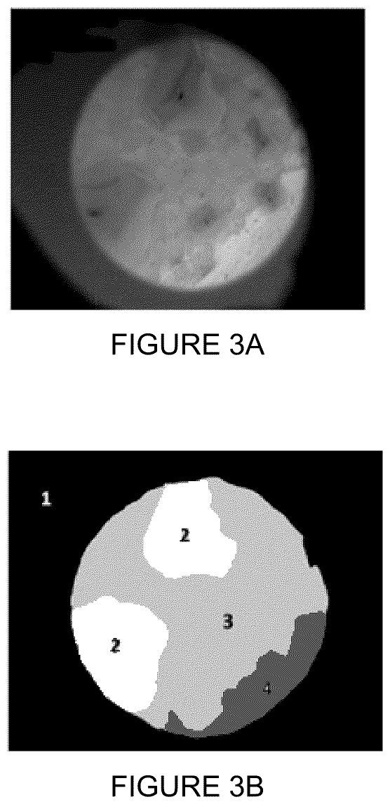

FIG. 3A illustrates an example view of a crucible 100 (shown in FIG. 1) in use. FIG. 3B illustrates an example labeling scheme for the of the crucible 100 in use shown in FIG. 3A.

The system uses semantic segmentation for a deep learning algorithm that associates a label or category to each pixel of an image. The segmentation is the process in which the image is divided into distinct regions which have common characteristics. The results of the segmentation process are an image with the same dimensions as the initial picture composed of solid-colored regions. The first step is the labeling process in which the goal was to obtain an equivalent image with the mask of each pixel marked according to the relevant class.

For this segmentation four different classes were chosen with four distinct colors: 1) Background (black); 2) Silicon melt liquid (blue); 3) Cullet (grey); and 4) Crucible (yellow). These colors were chosen for training and user purposes, but other colors may be used for the masks. FIG. 3A illustrates an image and FIG. 3B illustrates an image after labeling.

A plurality of training images can be generated to train the one or more models to identify classes in images. The process of training of a semantic segmentation network to classify images involves the following steps: 1) Analyze a collection of pixel-labeled images; 2) Create a semantic segmentation network and train the network to classify images into pixel categories; and 3) Evaluate the accuracy of the network. The one or more models described herein are trained for prediction and may be trained with either supervised or unsupervised learning.

The inference phase is the execution of the prediction of the segmentation algorithm using the model obtained after its training.

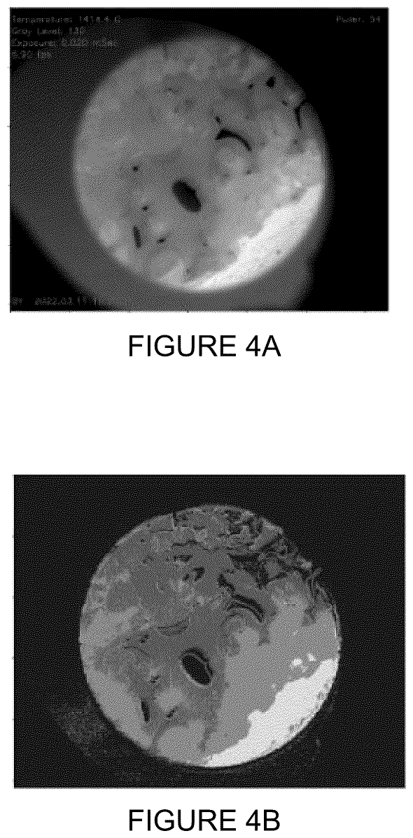

FIGS. 4A and 4B illustrate example views of a crucible 100 (shown in FIG. 1) in use before and after the image has been segmented using the labeling scheme shown in FIG. 3B.

FIG. 4A is the real picture or unprocessed picture and FIG. 4B is the relative mask picture in which the four different classes are divided by four distinct colors.

The number of pixels for each class are counted and dividing them by the total surface calculates the percentage of each class. For example, the percentage of silicon melt liquid can be calculated, and this percentage correlates with the micro-voids incorporation in the crystal.

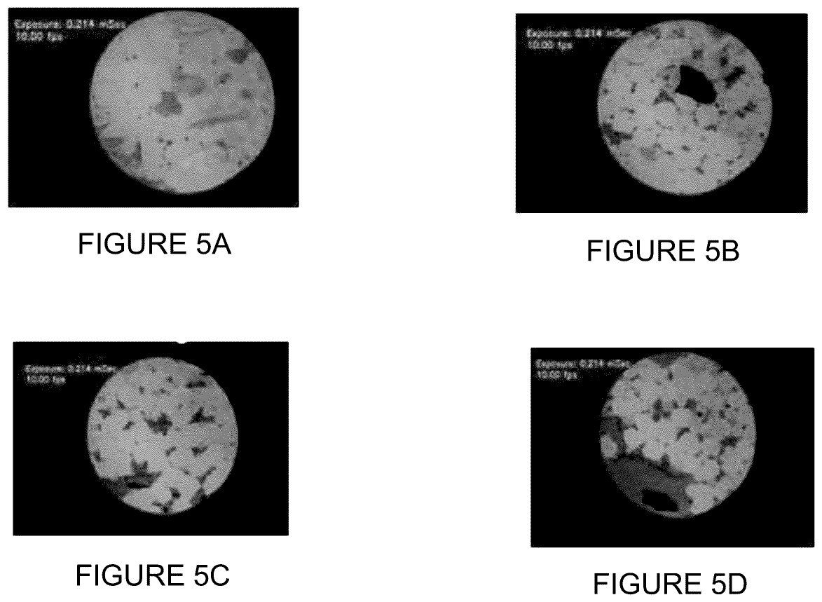

FIGS. 5A-5D illustrate example stages of crystal growth. More specifically, FIGS. 5A-5D illustrate the correlation between the micro-voids at 0.12 um for each crystal segment and the picture collected by the camera during the crystal body grown. From FIG. 5A to FIG. 5D a slight micro-voids increment is observed. This example is related to a child crystal with ratio higher than the critical threshold in which in the previous parent crystal was not discharged amount of cullet.

The FIG. 5A is the crystal portion between 10 cm and 45 cm, the FIG. 5B is the crystal portion between 45 cm and 80 cm, the FIG. 5C is the crystal portion between 80 cm and 114 cm, and the FIG. 5D the crystal portion between 114 cm and 148 cm. In this example, the crystal has a loss zero defect at 179 cm, and it is not possible to measure micro-voids after FIG. 5D.

The FIG. 5D has the 75 percentiles closer to 10 counts. The correlation between micro-voids counts and liquid zone on picture is clear. If the cullet distribution is compact (as shown in FIGS. 5A and 5B) no micro-voids are incorporated into the crystal. When a liquid zone starts to generate (shown in FIG. 5C), the micro-voids tend to be quite higher than in FIGS. 5A and 5B. When the liquid zone is consistent (shown in FIG. 5D), the micro-voids increase and tend to be closer to 10 counts. From the one or more models, it can be determined that to avoid the micro-voids incorporation increasing (higher than 10 counts) the liquid zone in the picture captured by the camera must be lower than one fourth of the total surface inspected by the camera. With the one or more models described, it is possible to quantify the liquid zone for each picture during the body phase and a warning message will appear if the liquid zone will be higher than one fourth of total surface.

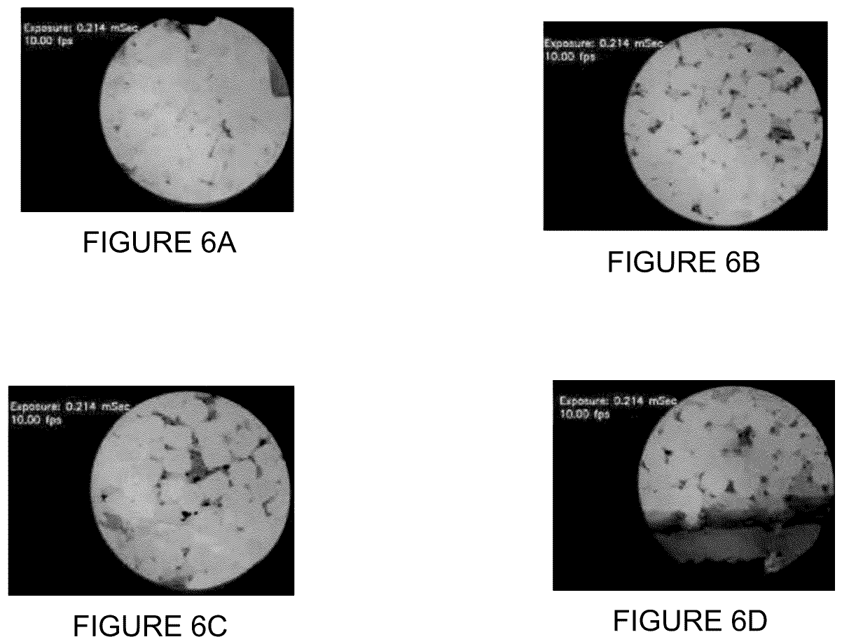

FIGS. 6A-6D illustrate further example stages of crystal growth. FIGS. 6A-6D illustrate another example case in which a child crystal with ratio higher than the critical threshold has high micro-voids number reported. Similar, to the previous example showed in FIGS. 5A-5D, it is from a child crystal in which in its parent crystal cullet was not discharged before the crystal body phase. In this case, micro-voids increasing was observed from Figure A to Figure D. The cullet distribution homogeneity is acceptable until Figure C. In the Figure D the liquid zone percentage is higher than one fourth of the total surface imaged and Figure D has the 75 percentiles higher than 10 counts.

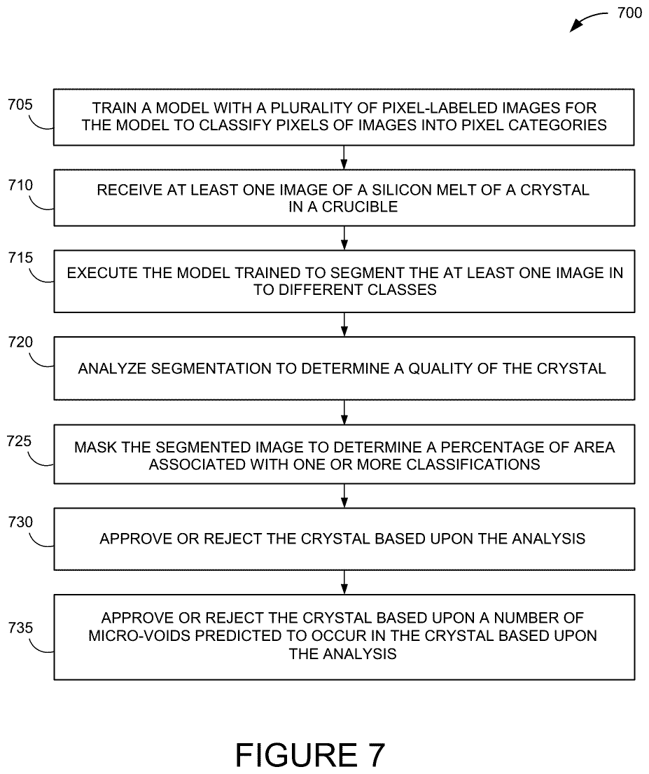

FIG. 7 illustrates an example process 700 of analyzing a Continuous Czochralski method. In the example embodiment, process 700 is performed by CCZIA server 810 (shown in FIG. 8).

In the example embodiment, the CCZIA server 810 trains 705 a model with a plurality of pixel-labeled images for the model to classify pixels of images into pixel categories. In some embodiments, the training 705 of the model includes the steps of 1) Analyze a collection of pixel-labeled images; 2) Create a semantic segmentation network and train the network to classify images into pixel categories; and 3) Evaluate the accuracy of the network. In some embodiments, the CCZIA server 810 is further programmed to train the model with a plurality of pixel-labeled images for the model to classify pixels of images into pixel categories. In at least one embodiment, the model is trained 705 to segment the at least one image into a plurality of segments including, but not limited to, background, silicon melt liquid, cullet, and crucible. In at least one embodiment, the model is a semantic segmentation network.

In the example embodiment, the CCZIA server 810 receives 710 at least one image of a silicon melt of a crystal in a crucible 100 (shown in FIG. 1). In the example embodiment, the at least one image is received 710 from a camera 825 (shown in FIG. 8) positioned perpendicular to an external silicon melt annulus. In the example embodiment, the silicon melt is associated with a Continuous Czochralski process. In the example embodiment, the crucible 100 is a triple crucible 100, as shown in FIG. 1.

In the example embodiment, the CCZIA server 810 executes 715 the model trained to segment the at least one image into different classes. In the example embodiment, the model is trained to segment the at least one image pixel by pixel. In at least one embodiment, the model generates an output of a segmented image.

In the example embodiment, the CCZIA server 810 analyzes 720 the segmentation of the at least one image to determine a quality of the crystal. IN at least one embodiment, the CCZIA server 810 masks 725 the segmented image to determine a percentage of area associated with one or more classifications.

In the example embodiment, the CCZIA server 810 approves or rejects 730 the crystal based upon the analysis. In some of these embodiments, the CCZIA server 810 approves or rejects 735 the crystal based upon a number of micro-voids predicted to occur in the crystal based upon the analysis. In some further embodiments, the CCZIA server 810 rejects the crystal if an area of silicon melt liquid exceeds one fourth of a total surface area in the crucible 100.

In some embodiments, the CCZIA server 810 takes one or more actions, instructs other computer devices and/or systems to take the one or more actions, and/or instructions one or more users to take the one or more actions based upon the approval and/or rejection 735 of the crystal. For the rejection 735 of the crystal, the one or more actions include, but are not limited to, stopping the crystal growth, removing the crystal, discharging a new amount of cullets into the crucible to reinstate the homogeneous distribution, and/or restart the growing of a new crystal.

In some further embodiments, the CCZIA server 810 retrains the model with a subsequent plurality of pixel-labeled images.

While the above describes using the systems and processes described herein for analyzing silicon melts in a CCz process, one having skill in the art would understand that these systems and methods may also be used for classifying other liquid melt situations.

FIG. 8 illustrates an example system 800 for performing the process 700 (shown in FIG. 7). In the example embodiment, the system 800 is used for analyzing image data to voids during a Continuous Czochralski method. In addition, the system 800 is a Continuous Czochralski image analysis (CCZIA) computer system configured to analyze crucible images.

As described below in more detail, the CCZIA server 810 is programmed to analyze crucible images to identify and count potential voids. In addition, the CCZIA server 810 is programmed to train one or more models to be used in the analysis of crucible images. The CCZIA server 810 is programmed to a) receive at least one image of a silicon melt of a crystal in a crucible 100; b) execute a model trained to segment the at least one image into different classes; c) analyze segmentation to determine a quality of the crystal; and/or d) approve or reject the crystal based upon the analysis.

In the example embodiment, client devices 805 are computers that include a web browser or a software application, which enables client devices 805 to communicate with CCZIA server 810 using the Internet, a local area network (LAN), or a wide area network (WAN). In some embodiments, the client devices 805 are communicatively coupled to the Internet through many interfaces including, but not limited to, at least one of a network, such as the Internet, a LAN, a WAN, or an integrated services digital network (ISDN), a dial-up-connection, a digital subscriber line (DSL), a cellular phone connection, a satellite connection, and a cable modem. Client devices 805 can be any device capable of accessing a network, such as the Internet, including, but not limited to, a desktop computer, a laptop computer, a personal digital assistant (PDA), a cellular phone, a smartphone, a tablet, a phablet, wearable electronics, smart watch, virtual headsets or glasses (e.g., AR (augmented reality), VR (virtual reality), or XR (extended reality) headsets or glasses), chat bots, voice bots, ChatGPT bots or ChatGPT-based bots, or other web-based connectable equipment or mobile devices.

In the example embodiment, CCZIA computer device 810 (also known as CCZIA server 810) is a computer that include a web browser or a software application, which enables CCZIA server 810 to communicate with client devices 805 and cameras/sensors 825 using the Internet, a local area network (LAN), or a wide area network (WAN). In some embodiments, the CCZIA server 810 is communicatively coupled to the Internet through many interfaces including, but not limited to, at least one of a network, such as the Internet, a LAN, a WAN, or an integrated services digital network (ISDN), a dial-up-connection, a digital subscriber line (DSL), a cellular phone connection, a satellite connection, and a cable modem. CCZIA server 810 can be any device capable of accessing a network, such as the Internet, including, but not limited to, a desktop computer, a laptop computer, a personal digital assistant (PDA), a cellular phone, a smartphone, a tablet, a phablet, wearable electronics, smart watch, virtual headsets or glasses (e.g., AR (augmented reality), VR (virtual reality), or XR (extended reality) headsets or glasses), chat bots, voice bots, ChatGPT bots or ChatGPT-based bots, or other web-based connectable equipment or mobile devices.

A database server 815 is communicatively coupled to a database 820 that stores data. In one embodiment, the database 820 is a database that includes one or more analysis models and/or analysis information. In some embodiments, the database 820 is stored remotely from the CCZIA server 810. In some embodiments, the database 820 is decentralized. In the example embodiment, a person can access the database 820 via the client devices 805 by logging onto CCZIA server 810.

Camera/sensor 825 may be any camera and/or sensor that the CCZIA server 810 is in communication with that transmits images to the CCZIA server 810. In the example embodiment, camera/sensors 825 that are in communication with CCZIA server 810 using the Internet, a local area network (LAN), or a wide area network (WAN). In some embodiments, the camera/sensor(s) 825 are communicatively coupled to the Internet through many interfaces including, but not limited to, at least one of a network, such as the Internet, a LAN, a WAN, or an integrated services digital network (ISDN), a dial-up-connection, a digital subscriber line (DSL), a cellular phone connection, a satellite connection, and a cable modem.

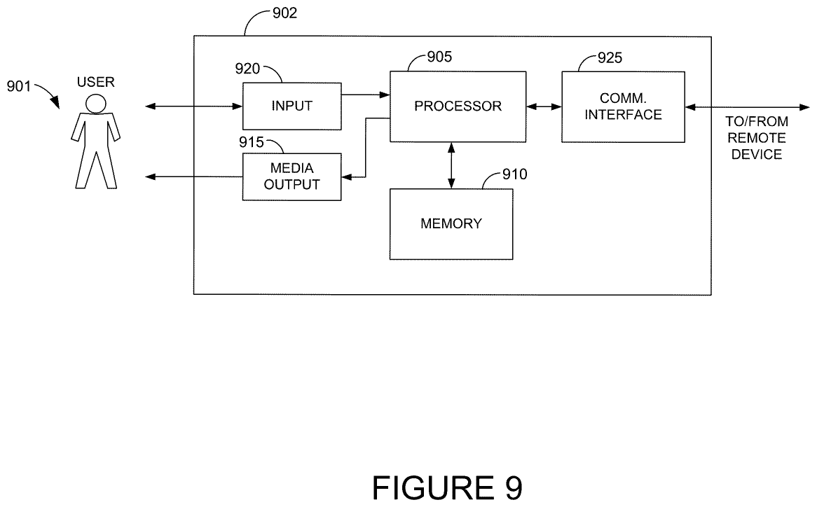

FIG. 9 depicts an example configuration 900 of user computer device 902. In the example embodiment, user computer device 902 may be similar to, or the same as, client device 805 (shown in FIG. 8). User computer device 902 may be operated by a user 901.

User computer device 902 may include a processor 905 for executing instructions. In some embodiments, executable instructions may be stored in a memory area 910. Processor 905 may include one or more processing units (e.g., in a multi-core configuration). Memory area 910 may be any device allowing information such as executable instructions and/or transaction data to be stored and retrieved. Memory area 910 may include one or more computer readable media.

User computer device 902 may also include at least one media output component 915 for presenting information to user 901. Media output component 915 may be any component capable of conveying information to user 901. In some embodiments, media output component 915 may include an output adapter (not shown) such as a video adapter and/or an audio adapter. An output adapter may be operatively coupled to processor 905 and operatively couplable to an output device such as a display device (e.g., a cathode ray tube (CRT), liquid crystal display (LCD), light emitting diode (LED) display, or “electronic ink” display) or an audio output device (e.g., a speaker or headphones).

In some embodiments, media output component 915 may be configured to present a graphical user interface (e.g., a web browser and/or a client application) to user 901. A graphical user interface may include, for example, an interface for viewing items of information provided by the CCZIA server 810 (shown in FIG. 8). In some embodiments, user computer device 902 may include an input device 920 for receiving input from user 901. User 901 may use input device 920 to, without limitation, submit information either through speech or typing.

Input device 920 may include, for example, a keyboard, a pointing device, a mouse, a stylus, a touch sensitive panel (e.g., a touch pad or a touch screen), a gyroscope, an accelerometer, a position detector, a biometric input device, and/or an audio input device. A single component such as a touch screen may function as both an output device of media output component 915 and input device 920.

User computer device 902 may also include a communication interface 925, communicatively coupled to a remote device such as CCZIA server 810. Communication interface 925 may include, for example, a wired or wireless network adapter and/or a wireless data transceiver for use with a mobile telecommunications network.

Stored in memory area 910 are, for example, computer readable instructions for providing a user interface to user 901 via media output component 915 and, optionally, receiving and processing input from input device 920. A user interface may include, among other possibilities, a web browser and/or a client application. Web browsers enable users, such as user 901, to display and interact with media and other information typically embedded on a web page or a website from CCZIA server 810. A client application may allow user 901 to interact with, for example, CCZIA server 810. For example, instructions may be stored by a cloud service, and the output of the execution of the instructions sent to the media output component 915.

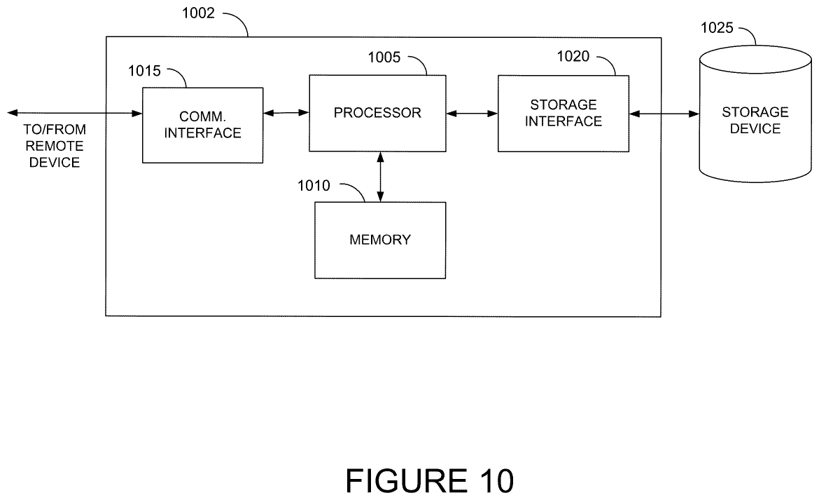

FIG. 10 depicts an example configuration 1000 of a server computer device 1002. In the example embodiment, server computer device 1002 may be similar to, or the same as, CCZIA server 810 and database server 815 (both shown in FIG. 8). Server computer device 1002 may also include a processor 1005 for executing instructions. Instructions may be stored in a memory area 1010. Processor 1005 may include one or more processing units (e.g., in a multi-core configuration).

Processor 1005 may be operatively coupled to a communication interface 1015 such that server computer device 1002 is capable of communicating with a remote device such as another server computer device 1002, CCZIA server 810, camera/sensors 825, and client devices 805 (shown in FIG. 8) (for example, using wireless communication or data transmission over one or more radio links or digital communication channels). For example, communication interface 1015 may receive input from client devices 805 via the Internet, as illustrated in FIG. 8.

Processor 1005 may also be operatively coupled to a storage device 1025. Storage device 1025 may be any computer-operated hardware suitable for storing and/or retrieving data, such as, but not limited to, data associated with one or more models. In some embodiments, storage device 1025 may be integrated in server computer device 1002. For example, server computer device 1002 may include one or more hard disk drives as storage device 1025.

In other embodiments, storage device 1025 may be external to server computer device 1002 and may be accessed by a plurality of server computer devices 1002. For example, storage device 1025 may include a storage area network (SAN), a network attached storage (NAS) system, and/or multiple storage units such as hard disks and/or solid-state disks in a redundant array of inexpensive disks (RAID) configuration.

In some embodiments, processor 1005 may be operatively coupled to storage device 1025 via a storage interface 1020. Storage interface 1020 may be any component capable of providing processor 1005 with access to storage device 1025. Storage interface 1020 may include, for example, an Advanced Technology Attachment (ATA) adapter, a Serial ATA (SATA) adapter, a Small Computer System Interface (SCSI) adapter, a RAID controller, a SAN adapter, a network adapter, and/or any component providing processor 1005 with access to storage device 1025.

Processor 1005 may execute computer-executable instructions for implementing aspects of the disclosure. In some embodiments, the processor 1005 may be transformed into a special purpose microprocessor by executing computer-executable instructions or by otherwise being programmed. For example, the processor 1005 may be programmed with the instruction such as illustrated in FIG. 7.

At least one of the technical problems addressed by this system may include: (i) improve analysis of wafers; (ii) decreased loss of material due to malfunction; (iii) earlier determination of wafer quality; (iv) increased accuracy in wafer analysis; and/or (v) increased accuracy in wafer analysis.

A technical effect of the systems and processes described herein may be achieved by performing at least one of the following steps: (i) receive at least one image of a silicon melt of a crystal in a crucible; (ii) execute a model trained to segment the at least one image into different classes; (iii) analyze segmentation to determine a quality of the crystal; and/or (iv) approve or reject the crystal based upon the analysis.

### Machine Learning and Other Matters

The computer-implemented methods discussed herein may include additional, less, or alternate actions, including those discussed elsewhere herein. The methods may be implemented via one or more local or remote processors, transceivers, servers, and/or sensors (such as processors, transceivers, servers, and/or sensors mounted on vehicles or mobile devices, or associated with smart infrastructure or remote servers), and/or via computer-executable instructions stored on non-transitory computer-readable media or medium.

In some embodiments, CCZIA server 810 is configured to implement machine learning, such that CCZIA server 810 “learns” to analyze, organize, and/or process data without being explicitly programmed. Machine learning may be implemented through machine learning methods and algorithms (“ML methods and algorithms”). In an example embodiment, a machine learning module (“ML module”) is configured to implement ML methods and algorithms. In some embodiments, ML methods and algorithms are applied to data inputs and generate machine learning outputs (“ML outputs”). Data inputs may include but are not limited to images. ML outputs may include, but are not limited to identified objects, items classifications, and/or other data extracted from the images. In some embodiments, data inputs may include certain ML outputs.

In some embodiments, at least one of a plurality of ML methods and algorithms may be applied, which may include but are not limited to: linear or logistic regression, instance-based algorithms, regularization algorithms, decision trees, Bayesian networks, cluster analysis, association rule learning, artificial neural networks, deep learning, combined learning, reinforced learning, dimensionality reduction, and support vector machines. In various embodiments, the implemented ML methods and algorithms are directed toward at least one of a plurality of categorizations of machine learning, such as supervised learning, unsupervised learning, and reinforcement learning.

In one embodiment, the ML module employs supervised learning, which involves identifying patterns in existing data to make predictions about subsequently received data. Specifically, the ML module is “trained” using training data, which includes example inputs and associated example outputs. Based upon the training data, the ML module may generate a predictive function which maps outputs to inputs and may utilize the predictive function to generate ML outputs based upon data inputs. The example inputs and example outputs of the training data may include any of the data inputs or ML outputs described above. In the example embodiment, a processing element may be trained by providing it with a large sample of images with known characteristics or features. Such information may include, for example, information associated with a plurality of images of a plurality of different objects, items, and/or melts.

In another embodiment, a ML module may employ unsupervised learning, which involves finding meaningful relationships in unorganized data. Unlike supervised learning, unsupervised learning does not involve user-initiated training based upon example inputs with associated outputs. Rather, in unsupervised learning, the ML module may organize unlabeled data according to a relationship determined by at least one ML method/algorithm employed by the ML module. Unorganized data may include any combination of data inputs and/or ML outputs as described above.

In yet another embodiment, a ML module may employ reinforcement learning, which involves optimizing outputs based upon feedback from a reward signal. Specifically, the ML module may receive a user-defined reward signal definition, receive a data input, utilize a decision-making model to generate a ML output based upon the data input, receive a reward signal based upon the reward signal definition and the ML output, and alter the decision-making model so as to receive a stronger reward signal for subsequently generated ML outputs. Other types of machine learning may also be employed, including deep or combined learning techniques.

Based upon these analyses, the processing element may learn how to identify characteristics and patterns that may then be applied to analyzing and classifying objects. This information may be used to determine which crystals to reject and which to approve.

### Additional Considerations

As will be appreciated based upon the foregoing specification, the above-described embodiments of the disclosure may be implemented using computer programming or engineering techniques including computer software, firmware, hardware or any combination or subset thereof. Any such resulting program, having computer-readable code means, may be embodied or provided within one or more computer-readable media, thereby making a computer program product, i.e., an article of manufacture, according to the discussed embodiments of the disclosure. The computer-readable media may be, for example, but is not limited to, a fixed (hard) drive, diskette, optical disk, magnetic tape, semiconductor memory such as read-only memory (ROM), and/or any transmitting/receiving medium such as the Internet or other communication network or link. The article of manufacture containing the computer code may be made and/or used by executing the code directly from one medium, by copying the code from one medium to another medium, or by transmitting the code over a network.

These computer programs (also known as programs, software, software applications, “apps,” or code) include machine instructions for a programmable processor and can be implemented in a high-level procedural and/or object-oriented programming language, and/or in assembly/machine language. As used herein, the terms “machine-readable medium” “computer-readable medium” refers to any computer program product, apparatus and/or device (e.g., magnetic discs, optical disks, memory, Programmable Logic Devices (PLDs)) used to provide machine instructions and/or data to a programmable processor, including a machine-readable medium that receives machine instructions as a machine-readable signal. The “machine-readable medium” and “computer-readable medium,” however, do not include transitory signals. The term “machine-readable signal” refers to any signal used to provide machine instructions and/or data to a programmable processor.

As used herein, the term “database” can refer to either a body of data, a relational database management system (RDBMS), or to both. As used herein, a database can include any collection of data including hierarchical databases, relational databases, flat file databases, object-relational databases, object-oriented databases, and any other structured collection of records or data that is stored in a computer system. The above examples are example only, and thus are not intended to limit in any way the definition and/or meaning of the term database. Examples of RDBMS' include, but are not limited to including, Oracle® Database, MySQL, IBM® DB2, Microsoft® SQL Server, Sybase®, and PostgreSQL. However, any database can be used that enables the systems and methods described herein. (Oracle is a registered trademark of Oracle Corporation, Redwood Shores, California; IBM is a registered trademark of International Business Machines Corporation, Armonk, New York; Microsoft is a registered trademark of Microsoft Corporation, Redmond, Washington; and Sybase is a registered trademark of Sybase, Dublin, California.)

As used herein, a processor may include any programmable system including systems using micro-controllers, reduced instruction set circuits (RISC), application specific integrated circuits (ASICs), logic circuits, and any other circuit or processor capable of executing the functions described herein. The above examples are example only and are thus not intended to limit in any way the definition and/or meaning of the term “processor.”

As used herein, the terms “software” and “firmware” are interchangeable and include any computer program stored in memory for execution by a processor, including RAM memory, ROM memory, EPROM memory, EEPROM memory, and non-volatile RAM (NVRAM) memory. The above memory types are example only and are thus not limiting as to the types of memory usable for storage of a computer program.

In another example, a computer program is provided, and the program is embodied on a computer-readable medium. In an example, the system is executed on a single computer system, without requiring a connection to a server computer. In a further example, the system is being run in a Windows® environment (Windows is a registered trademark of Microsoft Corporation, Redmond, Washington). In yet another example, the system is run on a mainframe environment and a UNIX® server environment (UNIX is a registered trademark of X/Open Company Limited located in Reading, Berkshire, United Kingdom). In a further example, the system is run on an iOS® environment (iOS is a registered trademark of Cisco Systems, Inc. located in San Jose, CA). In yet a further example, the system is run on a Mac OS® environment (Mac OS is a registered trademark of Apple Inc. located in Cupertino, CA). In still yet a further example, the system is run on Android® OS (Android is a registered trademark of Google, Inc. of Mountain View, CA). In another example, the system is run on Linux® OS (Linux is a registered trademark of Linus Torvalds of Boston, MA). The application is flexible and designed to run in various different environments without compromising any major functionality.

In some embodiments, the system includes multiple components distributed among a plurality of computing devices. One or more components may be in the form of computer-executable instructions embodied in a computer-readable medium. The systems and processes are not limited to the specific embodiments described herein. In addition, components of each system and each process can be practiced independent and separate from other components and processes described herein. Each component and process can also be used in combination with other assembly packages and processes.

As used herein, an element or step recited in the singular and proceeded with the word “a” or “an” should be understood as not excluding plural elements or steps, unless such exclusion is explicitly recited. Furthermore, references to “example” or “one example” of the present disclosure are not intended to be interpreted as excluding the existence of additional examples that also incorporate the recited features. Further, to the extent that terms “includes,” “including,” “has,” “contains,” and variants thereof are used herein, such terms are intended to be inclusive in a manner similar to the term “comprises” as an open transition word without precluding any additional or other elements.

Furthermore, as used herein, the term “real-time” refers to at least one of the time of occurrence of the associated events, the time of measurement and collection of predetermined data, the time to process the data, and the time of a system response to the events and the environment. In the examples described herein, these activities and events occur substantially instantaneously.

The patent claims at the end of this document are not intended to be construed under 35 U.S.C. § 112 (f) unless traditional means-plus-function language is expressly recited, such as “means for” or “step for” language being expressly recited in the claim(s).

This written description uses examples to disclose the disclosure, including the best mode, and also to enable any person skilled in the art to practice the disclosure, including making and using any devices or systems and performing any incorporated methods. The patentable scope of the disclosure is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal language of the claims.

What is claimed is:

1. A computer device comprising at least one processor in communication with at least one memory device, wherein the at least one processor programmed to:
receive at least one image of a silicon melt of a crystal in a crucible;
execute a model trained to segment the at least one image into different classes;
analyze segmentation to determine a quality of the crystal; and
approve or reject the crystal based upon the analysis.

2. The computer device of claim 1, wherein the silicon melt is associated with a Continuous Czochralski process.

3. The computer device of claim 2, wherein the crucible is a triple crucible.

4. The computer device of claim 1, wherein the model is trained to segment the at least one image pixel by pixel.

5. The computer device of claim 4, wherein the model generates an output of a segmented image.

6. The computer device of claim 5, wherein the at least one processor is further programmed to mask the segmented image to determine a percentage of area associated with one or more classifications.

7. The computer device of claim 4, wherein the model is trained to segment the at least one image into a plurality of segments including, but not limited to, background, silicon melt liquid, cullet, and crucible.

8. The computer device of claim 1, wherein the at least one processor is programmed to reject the crystal if an area of silicon melt liquid exceeds one fourth of a total surface area in the crucible.

9. The computer device of claim 1, wherein the model is a semantic segmentation network, and wherein the at least one processor is further programmed to train the model with a plurality of pixel-labeled images for the model to classify pixels of images into pixel categories.

10. The computer device of claim 9, wherein the at least one processor is further programmed to retrain the model with a subsequent plurality of pixel-labeled images.

11. The computer device of claim 1, wherein the at least one processor is further programmed to approve or reject the crystal based upon a number of micro-voids predicted to occur in the crystal based upon the analysis.

12. The computer device of claim 1, wherein the at least one image is received from a camera positioned perpendicular to an external silicon melt annulus.

13. A computer-implemented method performed by a computer system including at least one processor in communication with a chatbot and at least one memory device, the method comprising:
receiving at least one image of a silicon melt of a crystal in a crucible;
executing a model trained to segment the at least one image into different classes;
analyzing segmentation to determine a quality of the crystal; and
approving or rejecting the crystal based upon the analysis.

14. The computer-implemented method of claim 13, wherein the silicon melt is associated with a Continuous Czochralski process.

15. The computer-implemented method of claim 14, wherein the crucible is a triple crucible.

16. The computer-implemented method of claim 13, wherein the model is trained to segment the at least one image pixel by pixel.

17. The computer-implemented method of claim 16, wherein the model generates an output of a segmented image.

18. The computer-implemented method of claim 17 further comprising masking the segmented image to determine a percentage of area associated with one or more classifications.

19. The computer-implemented method of claim 16, wherein the model is trained to segment the at least one image into a plurality of segments including, but not limited to, background, silicon melt liquid, cullet, and crucible.

20. The computer-implemented method of claim 13 further comprising rejecting the crystal if an area of silicon melt liquid exceeds one fourth of a total surface area in the crucible.

21. The computer-implemented method of claim 13, wherein the model is a semantic segmentation network, and wherein the method further compromises training the model with a plurality of pixel-labeled images for the model to classify pixels of images into pixel categories.

22. The computer-implemented method of claim 21 further comprising retraining the model with a subsequent plurality of pixel-labeled images.

23. The computer-implemented method of claim 13 further comprising approving or rejecting the crystal based upon a number of micro-voids predicted to occur in the crystal based upon the analysis.

24. The computer-implemented method of claim 13, wherein the at least one image is received from a camera positioned perpendicular to an external silicon melt annulus.
